(19) United States
(12) Patent Application Publication
(10) Pub. No.: US 2025/0169094 A1
(43) Pub. Date: May 22, 2025

(54) TRANSISTOR AND METHOD OF FORMING THE SAME

(71) Applicant: National University of Singapore, Singapore (SG)

(72) Inventors: Chun-Kuei CHEN, Singapore (SG); Zihang FANG, Singapore (SG); Jieming PAN, Singapore (SG); Aaron Voon-Yew THEAN, Singapore (SG)

(21) Appl. No.: 18/522,338

(22) Filed: Nov. 29, 2023

(30) Foreign Application Priority Data
Nov. 20, 2023 (SG) 10202303268R

(51) Int. Cl. H01L 29/66; H01L 21/28; H01L 29/51; H01L 29/78; H10B 51/20

(52) U.S. Cl. CPC H10D 30/0415; H10B 51/20; H10D 30/701; H10D 64/033; H10D 64/689

(57) ABSTRACT

Various embodiments may relate to a transistor including a channel, a source and a drain in contact with opposite ends of the channel. The transistor may also include a first gate, and a first gate dielectric layer including a portion between the first gate and the channel. The transistor may also include a second gate, and a second gate dielectric layer including a portion between the second gate and the channel. The channel may include a first oxide-semiconductor layer including a first oxide-semiconductor material, a second oxide-semiconductor layer including a second oxide-semiconductor material, and a middle oxide-semiconductor layer between the first oxide-semiconductor layer and the second oxide-semiconductor layer, the middle oxide-semiconductor layer including a third oxide-semiconductor material. The third oxide-semiconductor material may have a bond dissociation energy lower than a bond dissociation energy of the first oxide-semiconductor material and a bond dissociation energy of the second oxide-semiconductor material.

### CROSS-REFERENCE TO RELATED APPLICATION

This application claims the benefit of priority of Singapore Application No. 10202303268R filed Nov. 20, 2023, the contents of it being hereby incorporated by reference in its entirety for all purposes.

### TECHNICAL FIELD

Various embodiments of this disclosure may relate to a transistor. Various embodiments of this disclosure may relate to a method of forming a transistor. Various embodiments of this disclosure may relate to an array or a device, e.g., a field programmable gate array (FPGA), including the transistor. Various embodiments of this disclosure may relate to a method of forming an array or a device including the transistor.

### BACKGROUND

The interest in the development of non-volatile interconnects as switches and power delivery networks is growing due to increasing demand for monolithic three-dimensional (M3D) integration, cloud data computation, reconfigurable computing, augmented reality (AR)/virtual reality (VR), flexible artificial intelligence integration, diverse Internet of Things (IoT) edge applications, and even defense technology. For example, reconfigurable field programmable gate array (FPGA) computing circuit-system architectures require reusable interconnects and could benefit significantly from low power consumption and high endurance. Similarly, power delivery networks such as the back-side power delivery systems proposed by others require a reconfigurable non-volatile switch device to achieve a more energy-efficient, routing-area saving design.

The conventional static random-access memory/multiplexer (SRAM/MUX) interconnect design which typically requires large on-chip global routing resources has been the bottleneck in reconfigurable computing and scaling. In field programmable gate arrays (FPGA), the conventional SRAM/MUX-based switch box accounts for 70% of the total area, 60% of the total power consumption, and 70% of the total time delay. Recently, it has been shown that utilizing an embedded two-terminal non-volatile memory (e.g., resistive random-access memory (RRAM)) as a programmable interconnect can provide a breakthrough in area efficiency, enhanced multifunctionality, greater power efficiency, and performance improvement compared to the conventional SRAM/MUX routing switches. Nevertheless, limited by 2-terminal operation, RRAM is subjected to noise from the interconnect signal as it passes through the memory element of the switch, hence reducing its stability and reliability. This issue can be solved using 3-terminal ferroelectric field-effect transistors (FeFETs), where the memory storage element is in the gate dielectric, and the routed signal current conducts between the transistor source and drain (S/D). However, an additional access transistor is typically required for a single-gated FeFET switch array implementation, leading to an increased routing area overhead. In addition, a 3-terminal single-gated FeFET as a non-volatile switch still faces the challenges of device structure and channel/interface defect passivation, which causes the memory-read-write disturbance, and memory read-after-write delay, respectively. As such, developing high-performance reconfigurable non-volatile interconnects to realize effective design of the on-chip computing architecture (e.g., FPGAs), and signal routing (e.g., backside power delivery network (BSPDN)) is still necessary.

### SUMMARY

Various embodiments may relate to a transistor including a channel, a source in contact with a first end of the channel, and a drain in contact with a second end of the channel opposite the first end. The transistor may also include a first gate. The transistor may additionally include a first gate dielectric layer including at least a portion between the first gate and the channel. The transistor may also include a second gate such that the channel is between the first gate and the second gate. The transistor may further include a second gate dielectric layer including at least a portion between the second gate and the channel. The channel may include a first oxide-semiconductor layer including a first oxide-semiconductor material, a second oxide-semiconductor layer including a second oxide-semiconductor material, and a middle oxide-semiconductor layer between the first oxide-semiconductor layer and the second oxide-semiconductor layer, the middle oxide-semiconductor layer including a third oxide-semiconductor material. The third oxide-semiconductor material may have a bond dissociation energy lower than a bond dissociation energy of the first oxide-semiconductor material and a bond dissociation energy of the second oxide-semiconductor material.

Various embodiments may relate to an array or a device including one or more transistors as described herein. Various embodiments may relate to a field programmable gate array (FPGA), e.g. a monolithic three-dimensional field programmable gate array (M3D FPGA).

Various embodiments may relate to a method of forming a transistor. The method may include forming a channel. The method may also include forming a source in contact with a first end of the channel. The method may further include forming a drain in contact with a second end of the channel opposite the first end. The method may additionally include forming a first gate. The method may also include forming a first gate dielectric layer including at least a portion between the first gate and the channel. The method may further include forming a second gate such that the channel is between the first gate and the second gate. The method may additionally include forming a second gate dielectric layer including at least a portion between the second gate and the channel. The channel may include a first oxide-semiconductor layer including a first oxide-semiconductor material. The channel may also include a second oxide-semiconductor layer including a second oxide-semiconductor material. The method may additionally include a middle oxide-semiconductor layer between the first oxide-semiconductor layer and the second oxide-semiconductor layer, The middle oxide-semiconductor layer may include a third oxide-semiconductor material. The third oxide-semiconductor material may have a bond dissociation energy lower than a bond dissociation energy of the first oxide-semiconductor material and a bond dissociation energy of the second oxide-semiconductor material.

Various embodiments may relate to a method of forming an array or a device including one or more transistors as described herein. Various embodiments may relate to a method of forming a field programmable gate array (FPGA), e.g. a monolithic three-dimensional field programmable gate array (M3D FPGA).

### BRIEF DESCRIPTION OF THE DRAWINGS

In the drawings, like reference characters generally refer to the same parts throughout the different views. The drawings are not necessarily drawn to scale, emphasis instead generally being placed upon illustrating the principles of various embodiments. In the following description, various embodiments of the invention are described with reference to the following drawings.

FIG. 1 shows a general illustration of a transistor according to various embodiments.

FIG. 2 shows a general illustration of a method of forming a transistor according to various embodiments.

FIG. 3 shows a cross-sectional schematic of a transistor according to various embodiments.

FIG. 4 shows a process flow of forming the transistor shown in FIG. 3 according to various embodiments.

FIG. 5A shows a plot of drive current (in arbitrary units or a.u.) as a function of channel type (in arbitrary units or a.u.) comparing the drive current of a conventional single-layer channel transistor and the drive current of a sandwich-layer transistor according to various embodiments.

FIG. 5B shows a plot of subthreshold swing (in arbitrary units or a.u.) as a function of channel type (in arbitrary units or a.u.) comparing the subthreshold swing of the conventional single-layer channel transistor and the subthreshold swing of the sandwich-layer transistor according to various embodiments.

FIG. 5C shows a plot of defect hysteresis (in arbitrary units or a.u.) as a function of channel type (in arbitrary units or a.u.) comparing the defect hysteresis of the conventional single-layer channel transistor and the defect hysteresis of the sandwich-layer transistor according to various embodiments.

FIG. 5D shows a plot of defect density (in arbitrary units or a.u.) as a function of channel type (in arbitrary units or a.u.) comparing the defect density of the conventional single-layer channel transistor and the defect density of the sandwich-layer transistor according to various embodiments.

FIG. 6A shows a plot of conductance (in siemens or S) as a function of switch programming (in arbitrary units or a.u.) illustrating the multi-memory states of the transistor based on different programming times according to various embodiments.

FIG. 6B shows a plot of pulse amplitude (in arbitrary units or a.u.) as a function of pulse width (in arbitrary units or a.u.) illustrating the variation of the On-state/Off-state conductance ratio of the transistor according to various embodiments as a function of memory programming pulse amplitude and pulse width.

FIG. 7A shows an interconnect switch array including a plurality of transistors according to various embodiments.

FIG. 7B shows a source-to-drain band diagram of the transistor according to various embodiments.

FIG. 7C shows a plot of array routing area (in arbitrary units or a.u.) as a function of switch type (in arbitrary units or a.u.) comparing the area of the interconnect switch array according to various embodiments with the area of a conventional one transistor-one ferroelectric field effect transistor (1T-1FeFET) switch array.

FIG. 8A shows a monolithic three-dimensional field programmable gate array (M3D FPGA) according to various embodiments.

FIG. 8B shows a schematic of a switch box (SB) with three routing tracks including a plurality of transistors according to various embodiments.

FIG. 9A shows a schematic of a routing track consisting of two independent routing paths, with each routing path including three transistors according to various embodiments.

FIG. 9B shows a schematic of a routing path in which the transistors according to various embodiments are configured in a single fan-out, single-way configuration.

FIG. 9C shows a schematic of the routing path in which the transistors according to various embodiments are configured in a multiple fan-out, dual-way configuration.

FIG. 10A shows a plot of the total field programmable gate array (FPGA) area (in arbitrary units or a.u.) as a function of FPGA type (in arbitrary units or a.u.) comparing the area of the monolithic three-dimensional field programmable gate array (M3D FPGA) according to various embodiments and the area of the conventional FPGA.

FIG. 10B shows a plot of the field programmable gate array (FPGA) energy (in arbitrary units or a.u.) as a function of FPGA type (in arbitrary units or a.u.) comparing the total FPGA energy of the monolithic three-dimensional field programmable gate array (M3D FPGA) according to various embodiments and the total FPGA energy of the conventional FPGA.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance, e.g. within 10% of the specified value.

As used herein, the term “and/or” includes any and all combinations of one or more of the associated listed items.

By “comprising” it is meant including, but not limited to, whatever follows the word “comprising”. Thus, use of the term “comprising” indicates that the listed elements are required or mandatory, but that other elements are optional and may or may not be present.

By “consisting of” is meant including, and limited to, whatever follows the phrase “consisting of”. Thus, the phrase “consisting of” indicates that the listed elements are required or mandatory, and that no other elements may be present.

Embodiments described in the context of one of the transistor/device/array are analogously valid for the other transistors/devices/arrays. Similarly, embodiments described in the context of a method are analogously valid for a transistor/device/array, and vice versa.

Various embodiments may relate to a 4-terminal transistor. Various embodiments may address one or more issues/shortcomings faced by conventional transistors or devices. Various embodiments may operate as a non-volatile logic switch, while other embodiments may operate as a volatile logic switch. Various embodiments may be used as a merged memory-logic device with independent memory and logic switch operations. Various embodiments may remove the need for the additional access transistor, as compared to a conventional 1 transistor (T)-1 memtransistor interconnect switch. Various embodiments may be more stable and reliable as compared to RRAM, since the read signal may not pass through the memory element. Various embodiments may reduce array size and/or have higher routing efficiency.

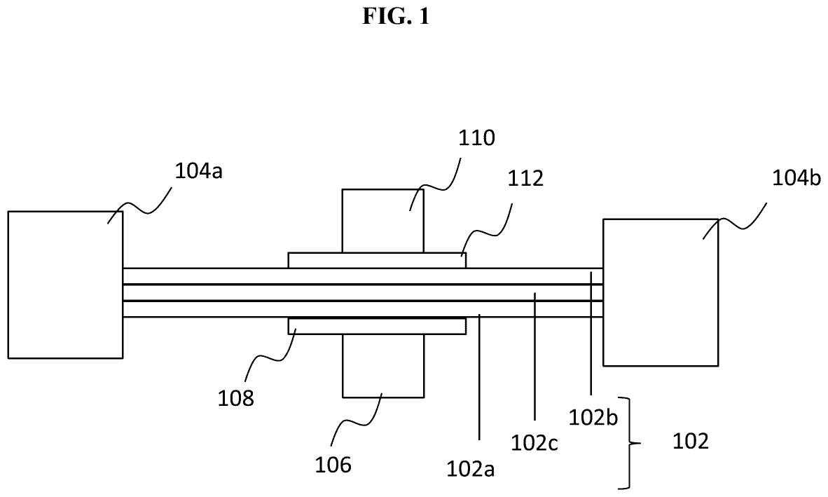

FIG. 1 shows a general illustration of a transistor according to various embodiments. The transistor may include a channel 102. The transistor may also include a source 104a in contact with a first end of the channel 102. The transistor may further include a drain 104b in contact with a second end of the channel 102 opposite the first end. The transistor may also include a first gate 106. The transistor may additionally include a first gate dielectric layer 108 including at least a portion between the first gate 106 and the channel 102. The transistor may also include a second gate 110 such that the channel 102 is between the first gate 106 and the second gate 110. The transistor may further include a second gate dielectric layer 112 including at least a portion between the second gate 110 and the channel 102. The channel 102 may include a first oxide-semiconductor layer 102a including a first oxide-semiconductor material, a second oxide-semiconductor layer 102b including a second oxide-semiconductor material, and a middle oxide-semiconductor layer 102c between the first oxide-semiconductor layer 102a and the second oxide-semiconductor layer 102b, the middle oxide-semiconductor layer 102c including a third oxide-semiconductor material. The third oxide-semiconductor material may have a bond dissociation energy lower than a bond dissociation energy of the first oxide-semiconductor material and a bond dissociation energy of the second oxide-semiconductor material. The transistor may alternatively be referred to as a dual-gated (DG) transistor/device or a sandwich-layer transistor.

In other words, the transistor may be a four-terminal transistor including a channel 102, a source 104a and a drain 104b adjoining opposite ends of the channel 102, as well as gates 106, 110 at opposite sides of the channel 102. The transistor may also include a first gate dielectric layer 108 between the first gate 106 and the channel 102, and a second gate dielectric layer 112 between the second gate 110 and the channel 102. The channel 102 may include a first oxide-semiconductor layer 102a, a second oxide-semiconductor layer 102b and a middle oxide-semiconductor layer 102c between the first oxide-semiconductor layer 102a and the second oxide-semiconductor layer 102b, with the material included in the middle oxide-semiconductor layer 102c having a lower bond dissociation energy compared to that included in the first oxide-semiconductor layer 102a. The material included in the middle oxide-semiconductor layer 102c may also have a lower bond dissociation energy compared to that included in the second oxide-semiconductor layer 102b.

For avoidance of doubt, FIG. 1 serves to illustrate features of the transistor according to various embodiments, and is not intended to limit the size, shape, arrangement, position, orientation etc. of the various features. For instance, while FIG. 1 shows the source 104a to the left of the channel 102 and the drain 104b to the right of the channel, it may be envisioned that in some embodiments, the source 104a is on the right of the channel 102 and the drain 104b is on the left of the channel 102.

Further, while FIG. 1 show the channel 102 over the first gate 106, and the second gate 110 over the channel 102, it may be envisioned that in some embodiments, the channel 102 may be over the second gate 110, and the first gate 106 may be over the channel 102. In such a case, the positions of the first gate dielectric layer 108 and the second gate dielectric layer 112 may be interchanged accordingly.

In other words, various embodiments may relate to a transistor including a first gate 106, a first gate dielectric layer 108 having at least a portion on or over the first gate 106, a channel 102 having at least a portion on or over the first gate dielectric layer 108, a second gate dielectric layer 112 on or over the channel 102 and a second gate 110 on or over the second gate dielectric layer 112, while various other embodiments may relate to a transistor including the second gate 110, a second gate dielectric layer 112 having at least a portion on or over the second gate 110, the channel 102 having at least a portion on or over the second gate dielectric layer 112, the first gate dielectric layer 108 on or over the channel 102 and the first gate 106 on or over the first gate dielectric layer 108.

In various embodiments, the first gate dielectric layer 108 may include any suitable dielectric material, e.g. silicon oxide or a high-k dielectric material (i.e. a dielectric material having a dielectric constant greater than the dielectric constant of silicon oxide). Examples of a high-k dielectric material may include but may not be limited to undoped hafnium oxide and undoped zirconium oxide. The second gate dielectric layer 112 may include a ferroelectric material. Examples of a ferroelectric material may include but may not be limited to lead zirconate titanate (PZT), hafnium zirconium oxide, barium titanate, lead titanate, doped hafnium oxide, and doped aluminum nitride.

By the second gate dielectric layer 112 having the ferroelectric material, the second gate 110 and the second gate dielectric layer 112 may be configured as a non-volatile switch or element. In various embodiments, during operation, a voltage of a first polarity may be applied to the second gate 110 to write a first logic state to the second gate dielectric layer 112, while a voltage of a second polarity opposite to the first polarity may be applied to the second gate 110 to write a second logic state. The ferroelectric domains in the second gate dielectric layer 112 may be aligned in parallel to store the first logic state, while 50% of the ferroelectric domains in the second gate dielectric layer 112 may be parallel (i.e. the ferroelectric domains are aligned in one particular direction) and the remaining 50% of the ferroelectric domains may have ferroelectric polarization alignments of random distribution (i.e. the remaining ferroelectric domains are not aligned in a particular direction) to store the second logic state. As such, the application of the voltages to the gate 110 may cause the second gate dielectric layer 112 to switch between a first logic state (in which the ferroelectric domains are aligned in parallel) and a second logic state (in which the 50% of the ferroelectric domains are parallel and 50% of the ferroelectric domains have ferroelectric polarization alignments of random distribution). The logic state may remain even when the voltage is no longer applied to the gate 110. In various embodiments, the second gate dielectric layer 112 may be programmed to have more than 2 logic states, e.g., by applying voltages to the second gate 110 for different durations such that different percentages of the ferroelectric domains are parallel. For instance, there may be a third logic state in which 75% of the ferroelectric domains are parallel, while the remaining 25% of the ferroelectric domains have ferroelectric polarization alignments of random distribution. In other words, different logic states may be programmed by using different programming times. Alternatively, the different logic states may be programmed by using different pulse amplitudes or different pulse widths.

On the other hand, the first dielectric layer 108 (including e.g., the high-k dielectric material) and the first gate 106 may be configured as a volatile switch or element.

The logic state stored in the second gate dielectric layer 112 may affect a conductance of the channel 102. As the non-volatile switch and the volatile switch share the same channel 102, the channel 102 or the transistor may be configured to have multiple conductance states. This may be made possible by using memory write and erase operations to store different logic states in the second gate dielectric layer 112 as mentioned above. Afterwards, the volatile gate may be used to read the conductance state of the channel 102. Various embodiments may utilize the non-volatile gate for memory write and erase operations, while the volatile gate may be used for read or logic operations. The independent operations of the non-volatile switch and the volatile switch may achieve high energy efficiency and high computation efficiency for in-memory computing applications. The dual gate transistor architecture to merge memory and logic functionalities into a single transistor may allow the transistor according to various embodiments to exhibit memory-logic switch operations that conventional single gate transistors cannot achieve. The transistor according to various embodiments may be utilized in non-logic applications to further enhance circuit reconfigurability and functionality.

In various other embodiments, the first gate dielectric layer 108 and the second gate dielectric layer 112 may include a dielectric material. The first gate dielectric layer 108 and the second gate dielectric layer 112 may include a dielectric material that is non-ferroelectric. In various embodiments, the first gate dielectric layer 108 and the second gate dielectric layer 112 may include a high-k dielectric material. In yet various other embodiments, the first gate dielectric layer 108 may include a first dielectric material that is non-ferroelectric, while the second gate dielectric layer 112 may include a second dielectric material that is different from the first dielectric material and which is also non-ferroelectric. The first dielectric material or the second dielectric material may be a high-k dielectric material, or both the first dielectric material and the second dielectric material may be high-k dielectric materials. The transistor according to various embodiments may be configured as a volatile backend-of-line (BEOL) compatible low thermal budget switch.

In various embodiments, the first oxide-semiconductor material and the second oxide-semiconductor material may be of a same material. In various other embodiments, the first oxide-semiconductor material and the second oxide-semiconductor material may be of different materials. The sandwich-layer channel 102 may suppress channel/interface defect numbers significantly and enhance electrical performance and reliability.

In various embodiments, the first oxide-semiconductor material and the second oxide-semiconductor material may be of any suitable oxide-semiconductor material, such as a material selected from a group consisting of indium tin zinc oxide (InSnZnOₓ), indium gallium zinc oxide doped with tin (InGaZnOₓ:Sn), indium oxide doped with tungsten (InOₓ:W), zinc oxide doped with tin (ZnOₓ:Sn) and indium gallium oxide (IGO). The examples as described herein, including any doping or post-deposition treatment, are non-limiting examples, and various other embodiments may include any other suitable material, including any suitable doping and/or any suitable post-deposition treatment. In various embodiments, the third oxide-semiconductor material may be of any suitable oxide-semiconductor material, such as a material selected from a group consisting of indium gallium zinc oxide (InGaZnOₓ), indium oxide (InOₓ), zinc oxide (ZnOₓ) and indium gallium oxide (IGO). The “x” as shown herein may represent any suitable positive number. The examples as described herein, including any doping or post-deposition treatment, are non-limiting examples, and various other embodiments may include any other suitable material, including any suitable doping and/or any suitable post-deposition treatment.

In various embodiments, the source 104a and/or the drain 104b may include a suitable electrically conductive material, e.g. a doped semiconductor material such as doped silicon or a metal such as aluminum (Al).

In various embodiments, the first gate 106 may include an electrically conductive material, e.g. a metal such as copper (Cu) or aluminum (Al). For instance, the first gate 106 may include one or more metal layers including a material such as Cu or Al, as well as one or more diffusion barrier layers including a material such as tantalum nitride (TaN), tantalum (Ta), titanium nitride (TiN), titanium tungsten (TiW) or any combination thereof (e.g. a stacked arrangement such as a TaN layer on a Ta layer). Likewise, the second gate 110 may include an electrically conductive material, e.g. a metal such as copper (Cu) or aluminum (Al). For instance, the second gate 110 may include one or more metal layers including a material such as Cu or Al, as well as one or more diffusion barrier layers including a material such as tantalum nitride (TaN), tantalum (Ta), titanium nitride (TiN), titanium tungsten (TiW), or any combination thereof (e.g. a stacked arrangement such as a TaN layer on a Ta layer). The diffusion barrier layers may help to reduce or prevent diffusion of metal from a wordline into the gates 106, 110, while electrically connecting the wordline to the gates 106, 110.

In various embodiments, the transistor may include a substrate, e.g. a wafer. The other components of the transistor, such as the channel 102, the source 104a, the drain 104b, the first gate 106, the first gate dielectric layer 108, the second gate 110 and the second gate dielectric 112 may be on or over the substrate.

In various embodiments, the transistor may include a first gate electrode in electrical connection with the first gate 106, and a second gate electrode in electrical connection with the second gate 110. In various embodiments, the transistor may also include a source electrode in electrical connection to the source 104a, and a drain electrode in electrical connection to the drain 104b.

Various embodiments may include an array, e.g. an interconnect array, including one or more transistors as described herein. The array may have negligible sneak path leakage. The array may be compatible with V/2 memory array programming method.

Various embodiments may relate to a field programmable gate array (FPGA), e.g. a monolithic three-dimensional field programmable gate array (M3D FPGA). The field programmable gate array (FPGA) may include a first layer or plane including a plurality of configurable logic blocks (CLB). The field programmable gate array (FPGA) may also include a second layer or plane including a plurality of switch boxes (SB) and a plurality of connection boxes (CB), the second layer or plane arranged vertically relative to the first layer or plane. Each of the plurality of switch boxes (SB) may include a plurality of transistors as described herein. Each of the plurality of transistors may include a channel, a source in contact with a first end of the channel, a drain in contact with a second end of the channel opposite the first end, a first gate, a first gate dielectric layer including at least a portion between the first gate and the channel, a second gate such that the channel is between the first gate and the second gate, and a second gate dielectric layer including at least a portion between the second gate and the channel. The channel may include a first oxide-semiconductor layer including a first oxide-semiconductor material, a second oxide-semiconductor layer including a second oxide-semiconductor material, and a middle oxide-semiconductor layer between the first oxide-semiconductor layer and the second oxide-semiconductor layer, the middle oxide-semiconductor layer including a third oxide-semiconductor material. The third oxide-semiconductor material may have a bond dissociation energy lower than a bond dissociation energy of the first oxide-semiconductor material and a bond dissociation energy of the second oxide-semiconductor material.

In various embodiments, the second layer or plane including the plurality of switch boxes (SB) may be over the first layer or plane including the plurality of configurable logic blocks (CLB). In various other embodiments, the first layer or plane including the plurality of configurable logic blocks (CLB) may be over the second layer or plane including the plurality of switch boxes (SB).

In various embodiments, the plurality of transistors may be arranged along a plurality of routing paths of a routing track of a respective switch box (SB) of the plurality of switch boxes (SB). In various embodiments, the plurality of routing paths may be two routing paths. However, there may be any suitable number of routing paths, e.g. three, four or more. In various embodiments, each switch box (SB) of the plurality of switch boxes (SB) may include six transistors. In various other embodiments, each switch box (SB) of the plurality of switch boxes (SB) may include any suitable number of transistors.

In various embodiments, the plurality of transistors may be configured such that the respective switch box (SB) is in a single fan-out configuration. In various other embodiments, the plurality of transistors may be configured such that the respective switch box (SB) is in a multiple fan-out configuration.

Various embodiments may relate to any device including one or more transistors as described herein. The device may be, for instance, a FPGA, a reconfigurable switch, a reconfigurable electronic fuse (eFuse), a multiplexer/demultiplexer, a non-volatile logic device, or a non-volatile memory.

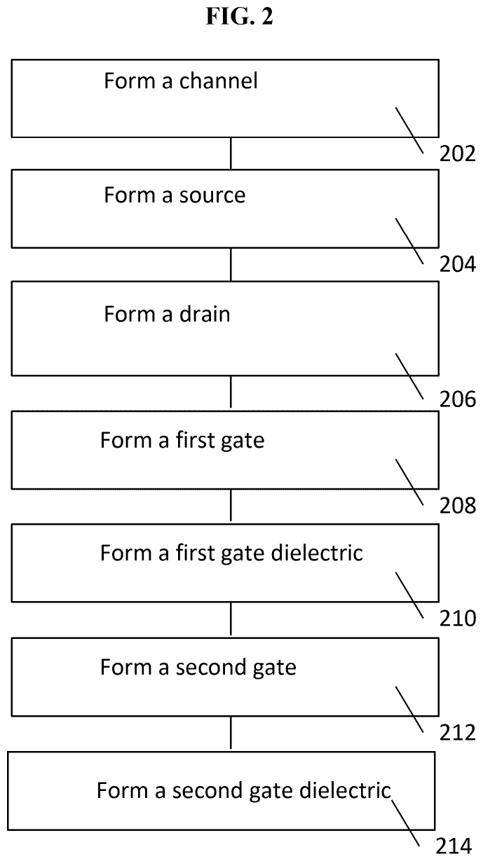

FIG. 2 shows a general illustration of a method of forming a transistor according to various embodiments. The method may include, in 202, forming a channel. The method may also include, in 204, forming a source in contact with a first end of the channel. The method may further include, in 206, forming a drain in contact with a second end of the channel opposite the first end. The method may additionally include, in 208, forming a first gate. The method may also include, in 210, forming a first gate dielectric layer including at least a portion between the first gate and the channel. The method may further include, in 212, forming a second gate such that the channel is between the first gate and the second gate. The method may additionally include, in 214, forming a second gate dielectric layer including at least a portion between the second gate and the channel. The channel may include a first oxide-semiconductor layer including a first oxide-semiconductor material. The channel may also include a second oxide-semiconductor layer including a second oxide-semiconductor material. The method may additionally include a middle oxide-semiconductor layer between the first oxide-semiconductor layer and the second oxide-semiconductor layer, The middle oxide-semiconductor layer may include a third oxide-semiconductor material. The third oxide-semiconductor material may have a bond dissociation energy lower than a bond dissociation energy of the first oxide-semiconductor material and a bond dissociation energy of the second oxide-semiconductor material.

For avoidance of doubt, FIG. 2 serves to illustrate certain steps according to various embodiments and is not intended to limit the sequence of the various steps. In one non-limiting example, the first gate dielectric layer may be formed after forming the first gate. The channel may be formed after forming the first gate dielectric layer. The source and drain may be formed after forming the channel. The second gate dielectric layer may be formed after forming the source and the drain. The second gate may be formed after forming the gate dielectric layer. The method may further include annealing after forming the second gate. The method may include annealing the structure including the channel, the source, the drain, the first gate, the first gate dielectric, the second gate and the second gate dielectric after forming the second gate.

In another non-limiting example, the second gate dielectric layer may be formed after forming the second gate. The channel may be formed after forming the second gate dielectric layer. The source and drain may be formed after forming the channel. The first gate dielectric layer may be formed after forming the source and the drain. The first gate may be formed after forming the gate dielectric layer. The method may further include annealing after forming the first gate. The method may include annealing the structure including the channel, the source, the drain, the first gate, the first gate dielectric, the second gate and the second gate dielectric after forming the first gate.

In various embodiments, the annealing may be carried out at a temperature below 400° C. The annealing may be carried out for channel activation and for ferroelectric phase formation. With a low thermal budget, the transistor may be compatible with monolithic three dimensional (M3D)-integrated systems in BEOL layer, BSPDN technologies, flexible electronics, and IoT-edge applications. The transistor may be included in a programmable interconnect array locally stacked over computing systems (e.g., silicon (Si)-based configurable logic blocks).

In various embodiments, the first gate dielectric layer may include a dielectric material, e.g. a high-k dielectric material. In various other embodiments, the first gate dielectric layer and the second gate dielectric layer may include a dielectric material, e.g., a high-k dielectric material. The first gate dielectric layer may also include a first dielectric material, while the second gate dielectric layer may include a second dielectric material different from the first dielectric material.

In various embodiments, the first oxide-semiconductor layer, the second oxide-semiconductor layer and the middle oxide-semiconductor layer may be formed via any suitable deposition method, such as sputtering.

In various embodiments, the structure including the channel, the source, the drain, the first gate, the first gate dielectric, the second gate and the second gate dielectric may be formed over a substrate.

In various embodiments, the first oxide-semiconductor material and the second oxide-semiconductor material may be of a same material. In various other embodiments, the first oxide-semiconductor material and the second oxide-semiconductor material may be of different materials.

In various embodiments, the first oxide-semiconductor material and the second oxide-semiconductor material may be of any suitable oxide-semiconductor material, such as a material selected from a group consisting of indium tin zinc oxide (InSnZnOₓ), indium gallium zinc oxide doped with tin (InGaZnOₓ:Sn), indium oxide doped with tungsten (InOₓ:W), zinc oxide doped with tin (ZnOₓ:Sn), and indium gallium oxide (IGO). The examples as described herein, including any doping or post-deposition treatment, are non-limiting examples, and various other embodiments may include any other suitable material, including any suitable doping and/or any suitable post-deposition treatment. In various embodiments, the third oxide-semiconductor material may be of any suitable oxide-semiconductor material, such as a material selected from a group consisting of indium gallium zinc oxide (InGaZnOₓ), indium oxide (InOₓ), indium gallium oxide (IGO) and zinc oxide (ZnOₓ). The “x” as shown herein may represent any suitable positive number. The examples as described herein, including any doping or post-deposition treatment, are non-limiting examples, and various other embodiments may include any other suitable material, including any suitable doping and/or any suitable post-deposition treatment.

Various embodiments may relate to forming a field programmable gate array (FPGA). The field programmable gate array (FPGA) may also include forming a plurality of switch boxes (SB) and a plurality of connection boxes (CB) vertically arranged relative to a plurality of configurable logic blocks (CLB).

Various embodiments may relate to a method forming a device including one or more transistors as described herein. The device may be, for instance, a FPGA, a reconfigurable switch, a reconfigurable electronic fuse (eFuse), a multiplexer/demultiplexer, a non-volatile logic device, or a non-volatile memory.

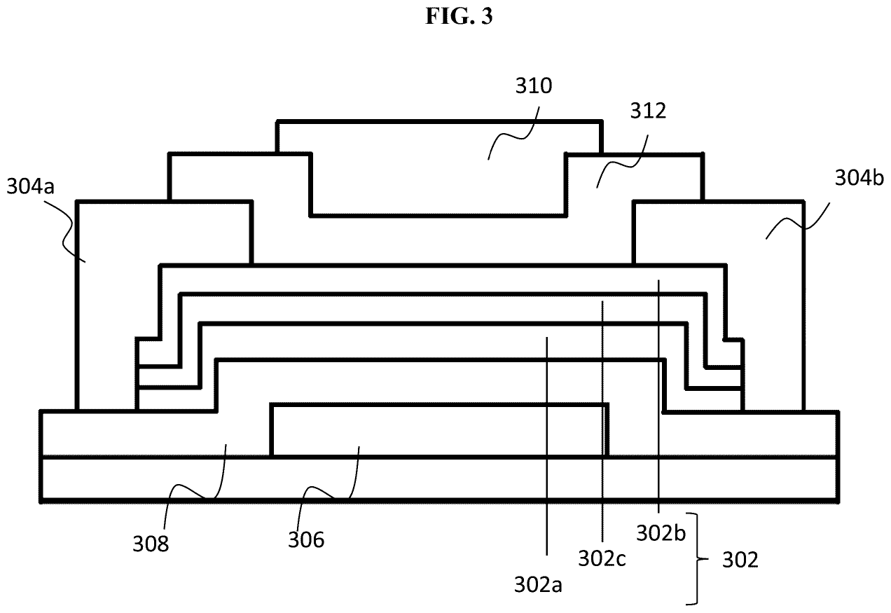

FIG. 3 shows a cross-sectional schematic of a transistor according to various embodiments. The transistor may be referred to as a dual-gated (DG) ferroelectric oxide-semiconductor-based ferroelectric field effect transistor (FeFET). The transistor may include a channel 302. The channel may include a first oxide-semiconductor layer 302a including a first oxide-semiconductor material, a second oxide-semiconductor layer 302b including a second oxide-semiconductor material, and a middle oxide-semiconductor layer 302c between the first oxide-semiconductor layer 302a and the second oxide-semiconductor layer 302b, the middle oxide-semiconductor layer 302c including a third oxide-semiconductor material. The transistor as shown in FIG. 3A may include a memory switch or element (alternatively referred to as ferroelectric field effect transistor or FeFET gate stack) and a logic switch or element (alternatively referred to as field effect transistor or FET gate stack) integrated as a merged memory-logic device.

The logic element or FET gate stack may include a first gate 306 and a first gate dielectric layer 308 including a portion between the first gate 306 and the channel 302. The first gate dielectric layer 308 may include a high-k dielectric material. The memory element or FeFET gate stack may include a second gate 310 and a second gate dielectric layer 312 including a portion between the second gate 310 and the channel 302. The second gate dielectric layer 312 may include a ferroelectric material. The memory element or FeFET gate stack may act as a non-volatile memory, while the logic element or FET gate stack may be used for effective channel conductance control. Both the memory element and the logic element may share the same sandwich-layer oxide-semiconductor channel 302. While FIG. 3 shows the memory element over the logic element, various other embodiments may relate to a transistor in which the logic element is over the memory element.

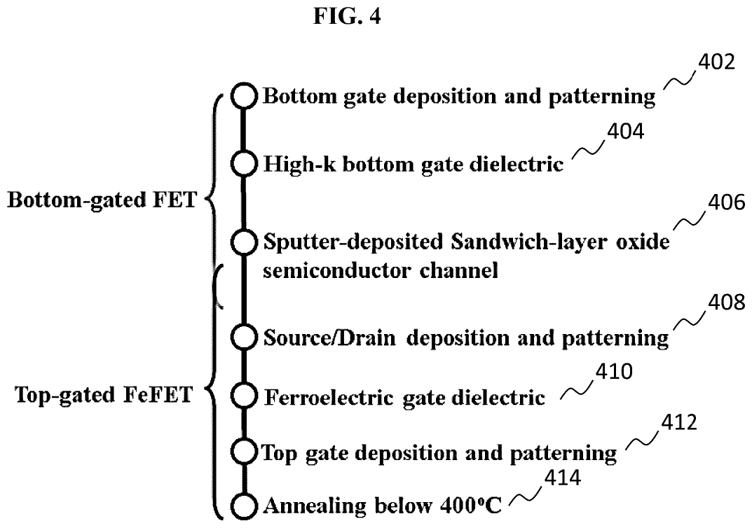

FIG. 4 shows a process flow of forming the transistor shown in FIG. 3 according to various embodiments. As shown in FIG. 4, the logic element (FET gate stack) may be formed before the memory stack (FeFET gate stack). The method may include, in 402, forming the first gate or bottom gate. The first gate or bottom gate may be formed by depositing a suitable gate material, and subsequently patterning the deposited gate material. The method may include, in 404, forming the first gate dielectric layer including the high-k dielectric material, after forming the first gate. The method may also include, in 406, forming the channel after forming the first gate dielectric layer. The method may additionally include, in 408, forming the source and drain after forming the channel. A suitable material may be deposited and subsequently patterned to form the source and the drain. The method may further include, in 410, forming the second gate dielectric layer including the ferroelectric material after forming the source and the drain. The method may additionally include, in 412, forming the second gate or top gate after forming the second gate dielectric layer. The second gate or top gate may be formed by depositing a suitable gate material, and subsequently patterning the deposited gate material. The method may also include, in 414, annealing at a temperature below 400° C.

Monolithic 3D (M3D) integration has become a promising method for achieving ultra-high-dense on-chip integration by stacking memory and logic devices on top of front-end-of-line (FEOL) layer silicon (Si)-based technology. However, embedding memory or logic devices in the back-end-of-line (BEOL) layer appears to have a process thermal budget limitation that arises from the tolerance of the BEOL copper (Cu)/Low-k vias interconnects process. This is because the Cu wires metal may diffuse and cause serious chip reliability issues when the process temperature is higher than 400° C. Therefore, it is important to develop a non-volatile logic device, which can be fabricated with the BEOL thermal budget limitation so that the devices are compatible with future M3D technology.

Various embodiments may be fabricated with an annealing temperature for channel activation and ferroelectric phase formation below 400° C. With such a low thermal budget, various embodiments may be utilized as reconfigurable interconnects, non-volatile logic devices, non-volatile sensors in M3D technology, and any IoT edge devices that cannot be fabricated with high temperature (E.g., flexible electronics, biomedical electronics, etc.)

As mentioned above, various embodiments may include a sandwich-layer oxide-semiconductor channel. The middle oxide-semiconductor layer may include an oxide-semiconductor material with lower bond dissociation energy (e.g., InGaZnOₓ, InOₓ, ZnOₓ, etc.). On the other hand, top and bottom oxide-semiconductor layers may include a oxide-semiconductor material or oxide-semiconductor materials with higher bond dissociation energy (e.g., InSnZnOₓ, InGaZnOₓ:Sn, InOₓ:W, ZnOₓ:Sn, etc.). Such a designed sandwich-layer oxide-semiconductor channel may significantly enhance electrical performance and reliability as shown below.

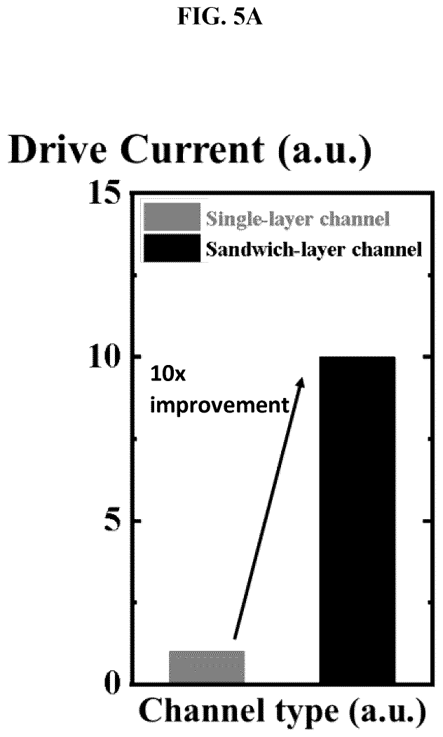

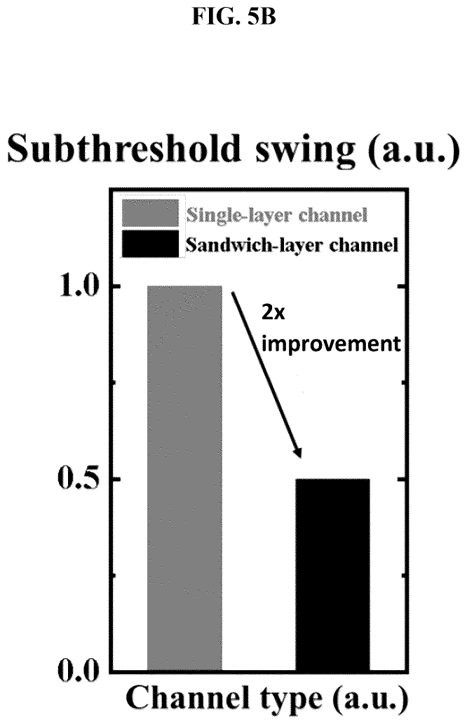

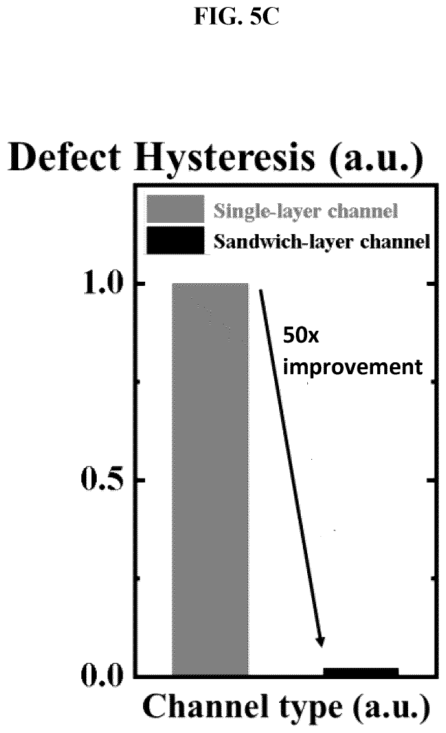

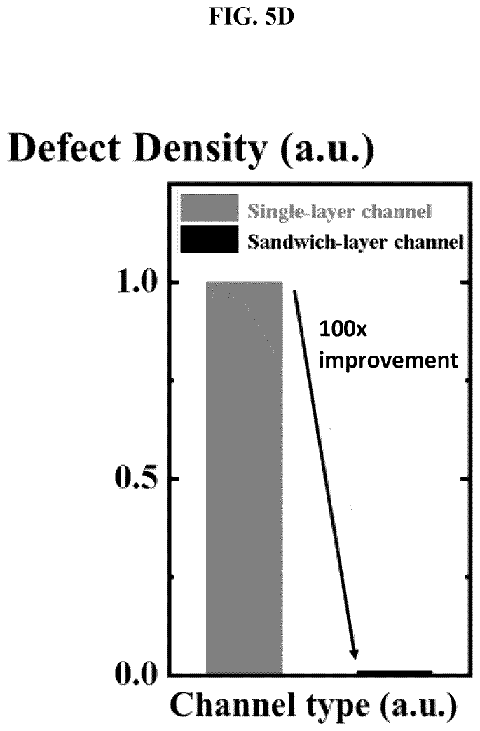

FIG. 5A shows a plot of drive current (in arbitrary units or a.u.) as a function of channel type (in arbitrary units or a.u.) comparing the drive current of a conventional single-layer channel transistor and the drive current of a sandwich-layer transistor according to various embodiments. FIG. 5B shows a plot of subthreshold swing (in arbitrary units or a.u.) as a function of channel type (in arbitrary units or a.u.) comparing the subthreshold swing of the conventional single-layer channel transistor and the subthreshold swing of the sandwich-layer transistor according to various embodiments. FIG. 5C shows a plot of defect hysteresis (in arbitrary units or a.u.) as a function of channel type (in arbitrary units or a.u.) comparing the defect hysteresis of the conventional single-layer channel transistor and the defect hysteresis of the sandwich-layer transistor according to various embodiments. FIG. 5D shows a plot of defect density (in arbitrary units or a.u.) as a function of channel type (in arbitrary units or a.u.) comparing the defect density of the conventional single-layer channel transistor and the defect density of the sandwich-layer transistor according to various embodiments.

A 10× improvement in drive current may mean that the transistor according to various embodiments can achieve higher current density for high-performance logic applications. The 2× improvement in subthreshold swing may translate to higher electrostatic control capability of the transistor according to various embodiments, which is critical for the switching speed of logic applications. The 50× reduction in defect hysteresis may significantly reduce noise and may increase the maximum number of quantizable states of the transistor according to various embodiments for memory operations, and may empower the transistor according to various embodiments with high reliability. The 100× reduction in defect density may suggest more device consistency that can improve the device yield and fabrication variability of the transistor according to various embodiments.

As mentioned above, various embodiments may relate to a device including a gate dielectric layer including a ferroelectric material. The ferroelectric material may be used as a memory component. When the transistor is used as a non-volatile interconnect switch, the memory state can be programmed through FeFET gate stack, while the FET gate stack may be responsible for the main control of the interconnect switch.

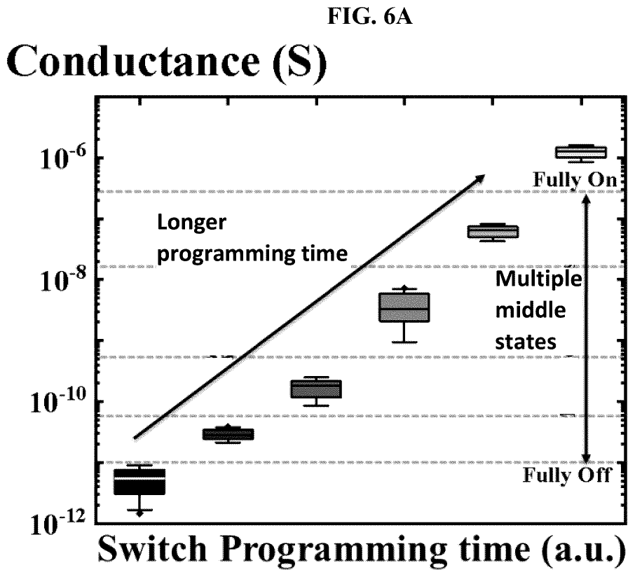

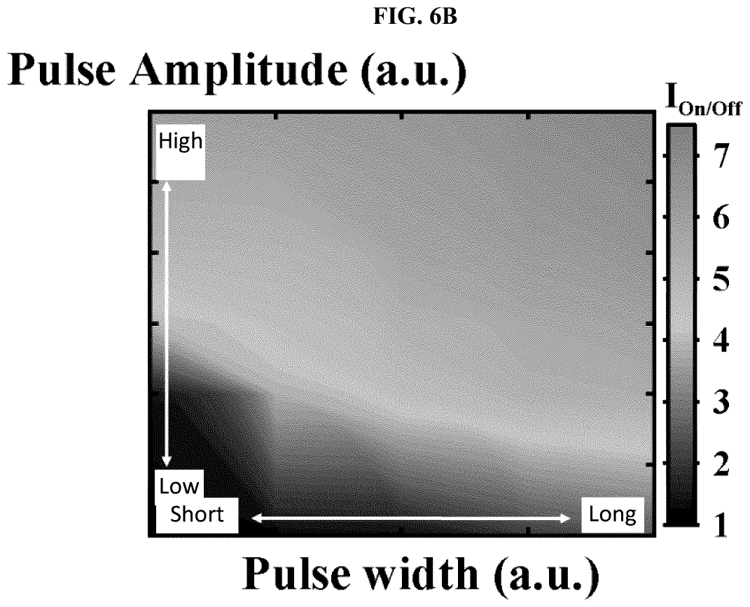

Since two gate stacks share the same oxide-semiconductor channel, the channel conductance state of the interconnect switch may be reconfigured according to the encoded ferroelectric state (i.e. logic state) by memory write/erase operations. After that, the interconnect switch may be turned on/off by controlling the FET gate stack. In various embodiments, the transistor may be operated as a non-volatile interconnect switch with multiple conductance states. FIG. 6A shows a plot of conductance (in siemens or S) as a function of switch programming (in arbitrary units or a.u.) illustrating the multi-memory states of the transistor based on different programming times according to various embodiments. This may allow the transistor to be used as an interconnect switch or in-interconnect computing. The conductance states of the non-volatile interconnect switch can be reconfigurable based on the requirement with the tunable On-state/Off-state conductance ratio from 101 to 107. FIG. 6B shows a plot of pulse amplitude (in arbitrary units or a.u.) as a function of pulse width (in arbitrary units or a.u.) illustrating the variation of the On-state/Off-state conductance ratio of the transistor according to various embodiments as a function of memory programming pulse amplitude and pulse width.

As such, a multi-function switch fabric functionality with high energy efficiency may be realized. For example, the memory state of the unused switches in a switch array may be programmed to off-state so that the current would not leak through the unused switches. Thus, the total power consumption may be reduced.

In various embodiments, the ferroelectric gate dielectric layer may be substituted by a high-k gate dielectric layer to form a volatile BEOL-compatible low-thermal-budget switch. As such, various embodiments may exhibit the flexibility to be designed as an M3D interconnect communication system. The system may include one or more volatile switches as described herein, and one or more non-volatile switches as described herein.

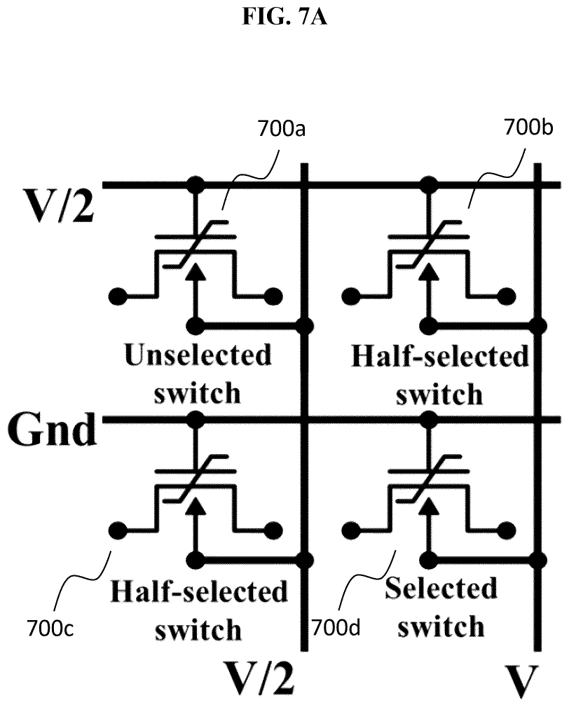

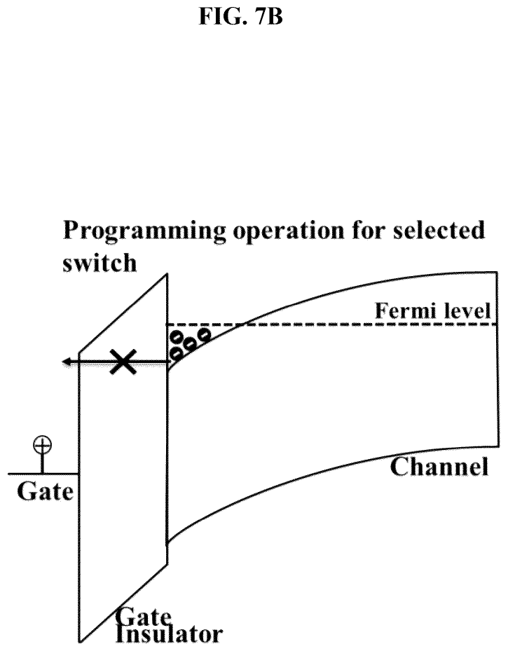

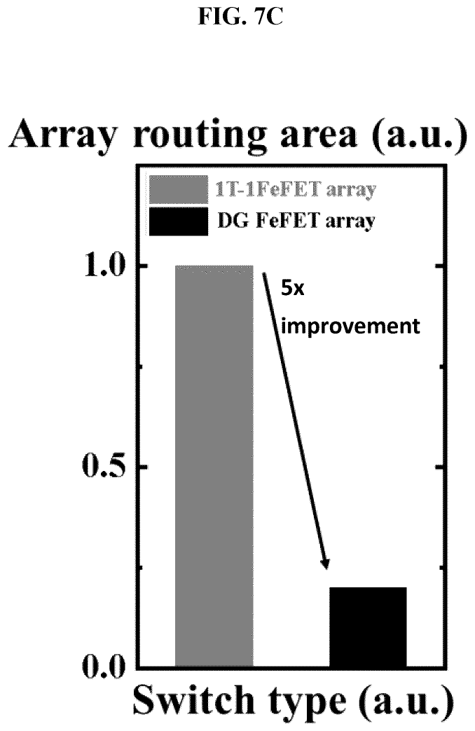

Various embodiments may be integrated into an interconnect switch array that can be compatible with a common V/2 or V/3 memory writing scheme. The interconnect switch array may include one or more transistors as described herein. FIG. 7A shows an interconnect switch array including a plurality of transistors 700a-d according to various embodiments. The interconnect switch array shown in FIG. 7A is based on the V/2 bias scheme. In order to write to a transistor, one gate would need to be biased at ground (Gnd), while the other gate would need to be biased at V. The interconnect switch array may have no or low sneak path leakage due to the high-quality gate dielectric layers or barriers that can effectively suppress the leakage path. FIG. 7B shows a source-to-drain band diagram of the transistor according to various embodiments. The band diagram shows the intrinsically low sneak path leakage mechanism. As such, the selected interconnect switch can be programmed without an additional access transistor. This may allow the interconnect switch array to achieve higher routing capability while with significant routing-area saving compared to the 1T-1FeFET scheme. FIG. 7C shows a plot of array routing area (in arbitrary units or a.u.) as a function of switch type (in arbitrary units or a.u.) comparing the area of the interconnect switch array according to various embodiments with the area of a conventional one transistor-one ferroelectric field effect transistor (1T-1FeFET) switch array.

In various embodiments, the logic or memory state may be encoded in the ferroelectric gate dielectric layer, which may be separated from the routed signal current path between the source and drain of the transistor. Therefore, the logic or memory state may not be disturbed when the signal current passes through the channel of the transistor. In contrast, in a conventional 2-terminal memristor-based (e.g., resistive random access memory or RRAM) programmable interconnect switch, the memory state is encoded along the path of the passing signal current, leading to unwanted memory read/write disturbance. This may become a major issue preventing the 2-terminal memristor-based programmable interconnect switch from becoming an effective and reliable programmable interconnect despite its merit of scalability.

It should be noted that the memory state of the transistor according to various embodiments may be free from (i.e. shielded from) main switch operations, which may be dominated by operations using the FET gate stack. The shielding may be due to the existence of the oxide semiconductor layers between the FET gate stack and the FeFET gate stack. The oxide semiconductor layers may act as a transistor channel as well as a barrier for switch operations. Therefore, various embodiments may achieve merged memory-logic functionality in a high-performance non-volatile reconfigurable switch without logic-operation disturbance.

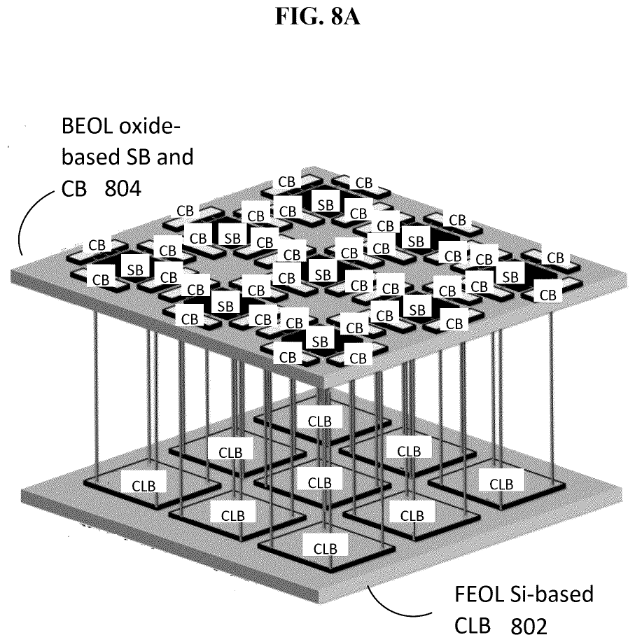

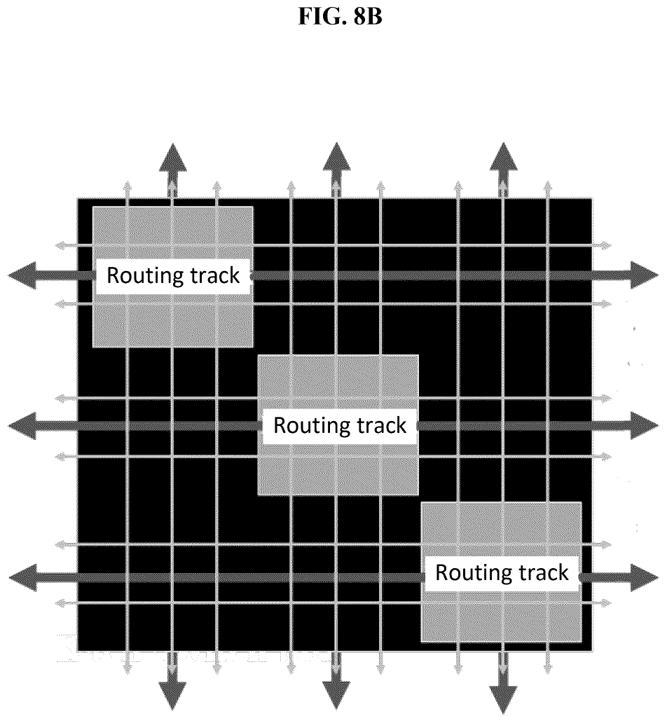

Various embodiments may relate to a field programmable gate array (FPGA), e.g., a monolithic three-dimensional field programmable gate array (M3D FPGA). FIG. 8A shows a monolithic three-dimensional field programmable gate array (M3D FPGA) according to various embodiments. The field programmable gate array (FPGA) may include a first layer (FEOL) 802 including a plurality of configurable logic blocks (CLB). The field programmable gate array (FPGA) may also include a second layer (BEOL) 804 including a plurality of switch boxes (SB) and a plurality of connection boxes (CB), the second layer (BEOL) 804 arranged above the first layer (FEOL) 802. Each of the plurality of switch boxes (SB) may be connected to 4 neighboring connection boxes (CB). Each of the plurality of switch boxes (SB) may include a plurality of transistors as described herein. Due to the low thermal budget process, transistors as described herein may be embedded into the BEOL layer, thereby empowering the various interconnect routing possibilities of the FPGA. The non-volatile M3D FPGA may be formed by replacing the conventional volatile static random access memory (SRAM)/multiplexer (MUX) switches with transistors according to various embodiments. As such, various embodiments may reduce the FPGA footprint area by vertically stacking switch boxes (SB) and connection boxes (CB) on top of silicon (Si)-based configurable logic blocks (CLB).

Each of the SBs may include or consist of 6 switches in a routing track. In each routing track, all the interconnects may share 2-word lines (WLs) and 3-bit lines (BLs), enabling the whole SB array to share a global switch control. FIG. 8B shows a schematic of a switch box (SB) with three routing tracks including a plurality of transistors according to various embodiments.

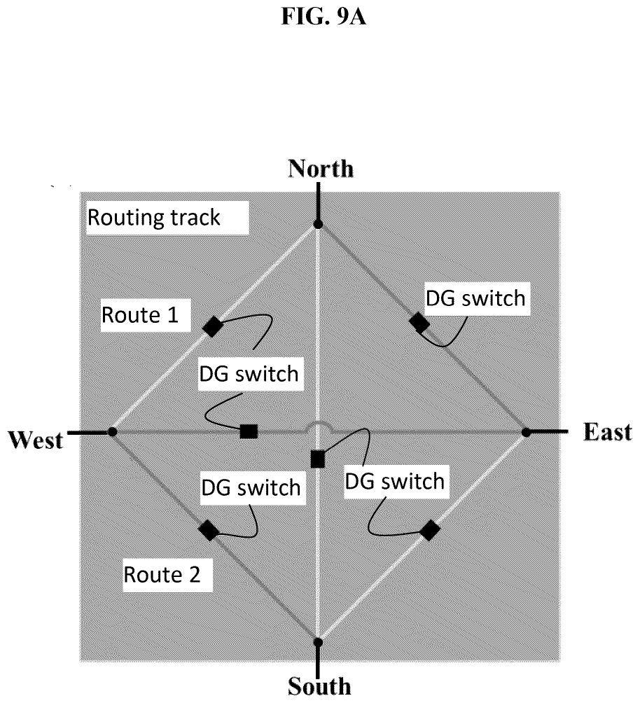

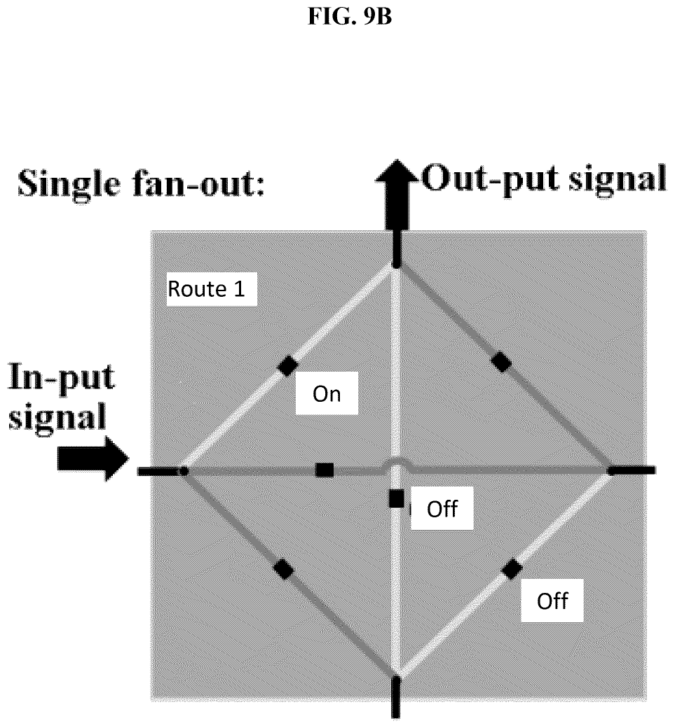

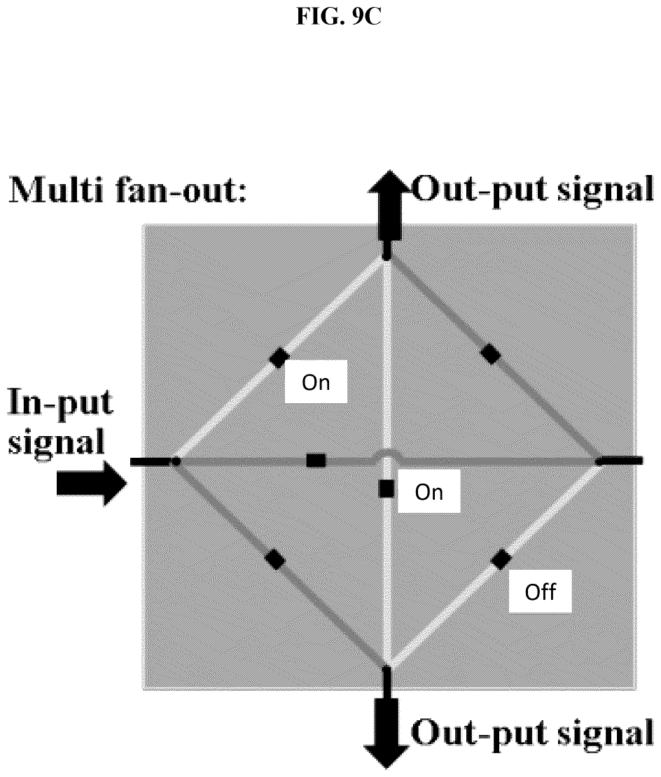

Each routing track may include two routing paths, connecting to FEOL CLB and the input-output (IO) pins of BEOL CB. Each routing path may be embedded with or may include three transistors (dual-gated switches or DG switches). FIG. 9A shows a schematic of a routing track consisting of two independent routing paths, with each routing path including three transistors according to various embodiments. The transistors are labelled as “DG switches”. The three DG switches can be programmed accordingly to configure the SB to be a single fan-out configuration (e.g., north (N) to south(S)), or multiple (multi) fan-out configuration (e.g., N to S, and N to west (W) simultaneously). For each routing path, the signal can also be transmitted by a single-way (e.g., W to N only) or dual-way (e.g., W to N, and W to S) communication. FIG. 9B shows a schematic of a routing path in which the transistors according to various embodiments are configured in a single fan-out, single-way configuration. FIG. 9C shows a schematic of the routing path in which the transistors according to various embodiments are configured in a multiple fan-out, dual-way configuration.

Such reconfigurable signal-communication direction with multi-function signal-processing capability may enable the transistor according to various embodiments to be utilized in future 3D-stacked neural-networks-integrated truly-on-chip systems.

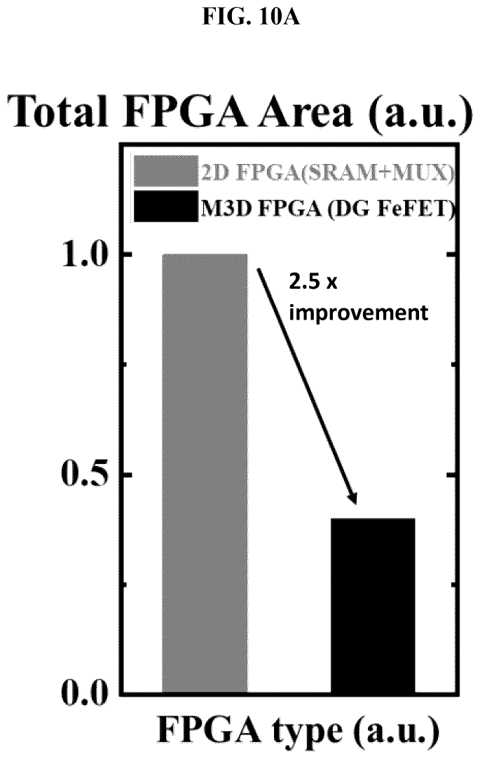

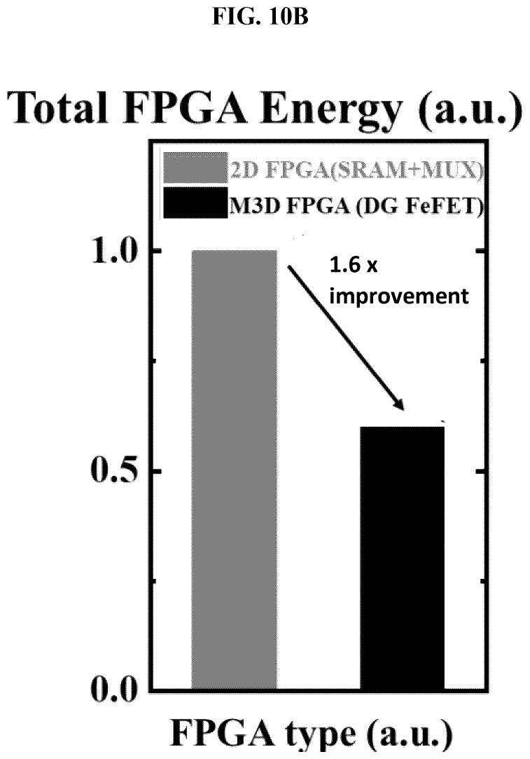

The proposed M3D FPGA is further investigated using computer compact modelling and customized place-and-route (P&R) tool, and compared with a conventional two-dimensional (2D) 7 nm-node SRAM/MUX-based FPGA. For effective comparison, the same logic block design may be adopted in the baseline model for both FPGA architectures. This may allow the FPGA routing area and energy of the two FPGA designs to be compared. Overall, the M3D FPGA according to various embodiments shows a 60% improvement in total area reduction and a 40% improvement in total energy reduction as compared to the conventional two-dimensional (2D) FPGA. FIG. 10A shows a plot of the total field programmable gate array (FPGA) area (in arbitrary units or a.u.) as a function of FPGA type (in arbitrary units or a.u.) comparing the area of the monolithic three-dimensional field programmable gate array (M3D FPGA) according to various embodiments and the area of the conventional FPGA. FIG. 10B shows a plot of the field programmable gate array (FPGA) energy (in arbitrary units or a.u.) as a function of FPGA type (in arbitrary units or a.u.) comparing the total FPGA energy of the monolithic three-dimensional field programmable gate array (M3D FPGA) according to various embodiments and the total FPGA energy of the conventional FPGA. The routing energy and the signal path delay show a 65% and 30% improvement, respectively.

Various embodiments may relate to a low-thermal-budget, high-performance DG device with a sandwich-layer oxide semiconductor channel as a merged memory-logic device. The DG device may exhibit excellent non-volatile interconnect properties including multi-memory-encoded state reconfigurability, high On-state/Off-state conductance ratio, dual-way signal communication, single-/multi-fan out, sneak-path leakage-free, memory read/write disturbance-free, and even radiation (rad)-hard properties. Various embodiments may be suitable for M3D FPGA architecture design which shows significant area-saving, energy-saving improvement, a higher speed operation as comparing to the conventional 2D FPGA. Various embodiments may exhibit a high potential to be utilized in several advanced non-volatile logic application domains: (1) Reconfigurable interconnect applications in BEOL and power delivery network systems; (2) In-interconnect signal-processing systems; (3) Reconfigurable in-memory, in-sensor, in-interconnect computing systems; (4) Reconfigurable non-volatile programmable logic gate technology; (5) Advanced non-volatile sensing and imaging; and/or (6) Mission-critical computation and memory technology in harsh environments.

As mentioned above, various embodiments may merge memory (FeFET gate stack) and logic (FET gate stack) into a single transistor. The device may therefore exhibit memory-logic switch operation that conventional single-gated FeFETs cannot achieve. Such a device can be utilized in non-volatile logic applications to further enhance circuit reconfigurability and functionality.

Various embodiments may be based on a very low thermal budget process (<400° C.). This may enable the device to be compatible with M3D-integrated systems in the BEOL layer, BSPDN technologies, flexible electronics, and IoT-edge applications. With the low-thermal budget process, various embodiments may be locally stacked on top of computing systems (e.g., Si-based configurable logic blocks).

Various embodiments may include a sandwich-layer oxide-semiconductor channel, which may suppress channel/interface defect numbers significantly and enhance electrical performance and reliability. A 10× improvement in drive current may mean the device can achieve higher current density for high-performance logic applications. The 50× reduction in defect hysteresis may significantly reduce noise, increase the maximum number of quantizable states for memory operation and empower the switch with high reliability. The 100× reduction in defect density may suggest more device consistency that can improve the device yield and fabrication variability.

Various embodiments may be compatible with conventional complementary metal oxide semiconductor (CMOS) processes. The utilized process integration tools, materials, device architecture, and process temperature for the proposed transistor may be fully compatible with the conventional CMOS process. Thus, it may be easy for the industry to apply this method for commercial non-volatile logic applications.

Various embodiments may have two gates to operate memory and logic functionalities independently. Thus, the switch may exhibit non-volatile conductivity that can be reconfigured by encoding the memory, while the On-state/Off-state of the switch may be mainly controlled by the logic element. This may be important to achieve high energy and computation efficiency for in-memory computing.

Various embodiments may eliminate the need for additional access transistors. Various embodiments may have routing area saving compared to conventional 1T-1Mem transistor switch array schemes. Due to the low thermal budget process, various embodiments may be designed as a 3D-stacked array that significantly reduces the routing area, and may empower various on-chip switch circuit designs.

With the memory-state reconfigurability, the unused non-volatile transistors according to various embodiments in the array can be reconfigured into stand-by mode, saving power consumption. In addition, the designed transistors may share the global switch control system. This may significantly reduce the density of power supplying circuits, saving routing energy consumption.

Various embodiments may also possess high endurance and faster switch speeds. Based on channel and ferroelectric material optimization, various embodiments may exhibit excellent memory endurance and fast switching speed. The 2× improvement in subthreshold swing may translate to higher electrostatic control capability of the switch, which may be critical for the switching speed of logic applications.

Various embodiments may be radiation-hard, and may be utilized in defense technology applications, such as computing systems in space, low-energy space-communication systems, etc.

Various embodiments may relate to an array that has negligible sneak path leakage, while being compatible with V/2 memory array programming method. The negligible sneak path leakage may be due to high-quality gate dielectric barriers that cut off the leakage path.

Various embodiments may be utilized as a non-volatile optical/heat/atmosphere sensor that can be utilized in the advanced sensor communication/computing systems. Various embodiments may exhibit potential for use in several advanced technology domains.

The materials used such as oxide semiconductors and ferroelectric materials may be sensitive to surrounding environmental temperature. However, optimization of the passivation layer process (e.g., BEOL dielectric layer process) may mitigate the effect of the post-deposition process, and may successfully reduce and control sensitivity to surrounding environmental temperature. Also, the oxide-semiconductor layer may be sensitive to channel defects formation due to exposure to different atmospheres in the different processes (before forming the passivation layer. The issue may be addressed by developing an effective channel defects passivation by defect self-compensation effect.

Various embodiments may be used as reconfigurable interconnects in FPGA. The low-thermal-budget DG switches may be compatible with the M3D technology according to various embodiments to achieve on-chip, area-saving, low-energy, high-density, reconfigurable non-volatile FPGAs. This may be impossible to be achieved by conventional volatile FPGA based on the SRAM/MUX interconnects. Various embodiments may lead to significant reduction in routing-area, and may address various routing-energy issues. The high-performance FPGAs according to various embodiments may enable fast, efficient, nonvolatile and enhanced computation for IoT edge applications, autonomous driving, robotics, remote sensing and automation, artificial intelligence (AI)/virtual reality (VR) and many other reconfigurable and low-energy technology applications.

Various embodiments may be used in advanced in-interconnect signal processing systems. Various embodiments may enable multi-function data processing (E.g., signal filtering, modulation, conversion, etc.) during the signal transformation for on-chip signal communication systems. This may be especially useful for in-sensor, in-memory, and in-interconnect computing systems.

Various embodiments may be used in in-interconnect computing systems. Various embodiments may be utilized as a non-volatile interconnect between different deep-learning computing units (e.g., deep neural networks (DNN), recurrent neural networks (RNN), long short-term memory (LSTM), etc.) to enable reconfigurable in-memory-computing systems that can reduce data transmission and hence power and signal losses significantly.

Various embodiments may be used in power delivery network (BSPDN) systems. Various embodiments may be integrated with power delivery networks technology (PDN) as a non-volatile interconnect or a non-volatile footer/header transistor. In such a case, our DG interconnects will empower the power supply distribution with reconfigurability, higher network design flexibility, energy efficiency, and routing saving and enable modular computing.

Various embodiments may be used in advanced reconfigurable non-volatile logic gate technology. Various embodiments may be utilized as a single merged-memory-logic transistor to build up a reconfigurable non-volatile logic gate circuit, the basic logic computing element on the chip. For example, various embodiments can be integrated into a single logic gate circuit that can perform NAND, NOR, and XOR gate functionality. This may significantly enhance circuit computing density, diverse logic-gate circuit functionality, and empower hardware security.

Various embodiments may be used in advanced non-volatile sensing and imaging. Various embodiments may be utilized as a non-volatile optical/heat/atmosphere sensor with the capability of in-sensor computing, such as imaging recognition, ultraviolet (UV)-light in-sensor computing, ozone monitoring, etc.

Various embodiments may enable computation systems in harsh environments. The rad-hard properties in various embodiments may allow various embodiments to withstand radiation in harsh environments, this may be extremely important for technologies that operate in high altitudes or space.

Various embodiments may relate to any device including one or more transistors as described herein. The device may be, for instance, a FPGA, a reconfigurable switch, a reconfigurable electronic fuse (eFuse), a multiplexer/demultiplexer, a non-volatile logic device, or a non-volatile memory.

1. A transistor comprising:
a channel;
a source in contact with a first end of the channel;
a drain in contact with a second end of the channel opposite the first end;
a first gate;
a first gate dielectric layer including at least a portion between the first gate and the channel;
a second gate such that the channel is between the first gate and the second gate;
a second gate dielectric layer including at least a portion between the second gate and the channel;
wherein the channel comprises:
a first oxide-semiconductor layer comprising a first oxide-semiconductor material;
a second oxide-semiconductor layer comprising a second oxide-semiconductor material; and
a middle oxide-semiconductor layer between the first oxide-semiconductor layer and the second oxide-semiconductor layer, the middle oxide-semiconductor layer comprising a third oxide-semiconductor material; and
wherein the third oxide-semiconductor material has a bond dissociation energy lower than a bond dissociation energy of the first oxide-semiconductor material and a bond dissociation energy of the second oxide-semiconductor material.

2. The transistor according to claim 1,
wherein the first gate dielectric layer comprises a dielectric material; and
wherein the second gate dielectric layer comprises a ferroelectric material.

3. The transistor according to claim 2,
wherein the channel is configured to have multiple conductance states.

4. The transistor according to claim 1,
wherein the first gate dielectric layer and the second gate dielectric layer comprise a dielectric material.

5. The transistor according to claim 1,
wherein the first oxide-semiconductor material and the second oxide-semiconductor material are of a same material.

6. The transistor according to claim 1,
wherein the first oxide-semiconductor material and the second oxide-semiconductor material are of different materials.

7. The transistor according to claim 1,
wherein the first oxide-semiconductor material and the second oxide-semiconductor material are of a material selected from a group consisting of indium tin zinc oxide, indium gallium zinc oxide doped with tin, indium oxide doped with tungsten, zinc oxide doped with tin, and indium gallium oxide.

8. The transistor according to claim 1,
wherein the third oxide-semiconductor material is of a material selected from a group consisting of indium gallium zinc oxide, indium oxide, zinc oxide, and indium gallium oxide.

9. A field programmable gate array (FPGA), the field programmable gate array (FPGA) comprising:
a first layer comprising a plurality of configurable logic blocks (CLB);
a second layer comprising a plurality of switch boxes (SB) and a plurality of connection boxes (CB), the second layer arranged vertically relative to the first layer;
wherein each of the plurality of switch boxes (SB) comprises a plurality of transistors, each of the plurality of transistors comprising:
a channel;
a source in contact with a first end of the channel;
a drain in contact with a second end of the channel opposite the first end;
a first gate;
a first gate dielectric layer including at least a portion between the first gate and the channel;
a second gate such that the channel is between the first gate and the second gate;
a second gate dielectric layer including at least a portion between the second gate and the channel;
wherein the channel comprises:
a first oxide-semiconductor layer comprising a first oxide-semiconductor material;
a second oxide-semiconductor layer comprising a second oxide-semiconductor material; and
a middle oxide-semiconductor layer between the first oxide-semiconductor layer and the second oxide-semiconductor layer, the middle oxide-semiconductor layer comprising a third oxide-semiconductor material; and
wherein the third oxide-semiconductor material has a bond dissociation energy lower than a bond dissociation energy of the first oxide-semiconductor material and a bond dissociation energy of the second oxide-semiconductor material.

10. The field programmable gate array (FPGA) according to claim 9,
wherein the second layer comprising the plurality of switch boxes (SB) are over the first layer comprising the plurality of configurable logic blocks (CLB).

11. The field programmable gate array (FPGA) according to claim 9,
wherein the first layer comprising the plurality of configurable logic blocks (CLB) are over the second layer comprising the plurality of switch boxes (SB).

12. The field programmable gate array (FPGA) according to claim 9,
wherein the plurality of transistors is arranged along a plurality of routing paths of a routing track of a respective switch box (SB) of the plurality of switch boxes (SB).

13. The field programmable gate array (FPGA) according to claim 12,
wherein the plurality of transistors is configured such that the respective switch box (SB) is in a single fan-out configuration.

14. The field programmable gate array (FPGA) according to claim 12,
wherein the plurality of transistors is configured such that the respective switch box (SB) is in a multiple fan-out configuration.

15. A method of forming a transistor, the method comprising:
forming a channel;
forming a source in contact with a first end of the channel;
forming a drain in contact with a second end of the channel opposite the first end;
forming a first gate;
forming a first gate dielectric layer including at least a portion between the first gate and the channel;
forming a second gate such that the channel is between the first gate and the second gate;
forming a second gate dielectric layer including at least a portion between the second gate and the channel;
wherein the channel comprises:
a first oxide-semiconductor layer comprising a first oxide-semiconductor material;
a second oxide-semiconductor layer comprising a second oxide-semiconductor material; and
a middle oxide-semiconductor layer between the first oxide-semiconductor layer and the second oxide-semiconductor layer, the middle oxide-semiconductor layer comprising a third oxide-semiconductor material; and
wherein the third oxide-semiconductor material has a bond dissociation energy lower than a bond dissociation energy of the first oxide-semiconductor material and a bond dissociation energy of the second oxide-semiconductor material.

16. The method according to claim 14,
wherein the first gate dielectric layer is formed after forming the first gate;
wherein the channel is formed after forming the first gate dielectric layer;
wherein the source and the drain are formed after forming the channel;
wherein the second gate dielectric layer is formed after forming the source and the drain;
wherein the second gate is formed after forming the gate dielectric layer; and
wherein the method further comprises annealing after forming the second gate.

17. The method according to claim 16,
wherein annealing is carried out at a temperature below 400° C.

18. The method according to claim 15,
wherein the first gate dielectric layer comprises a dielectric material; and
wherein the second gate dielectric layer comprises a ferroelectric material.

19. The method according to claim 5,
wherein the first gate dielectric layer and the second gate dielectric layer comprise a dielectric material.

20. The method according to claim 15,
wherein the first oxide-semiconductor layer, the second oxide-semiconductor layer and the middle oxide-semiconductor layer are formed via sputtering.
